(19) United States
(12) Patent Application Publication
(10) Pub. No.: US 2025/0105182 A1
(43) Pub. Date: Mar. 27, 2025

(54) SEMICONDUCTOR CHIP AND SEMICONDUCTOR PACKAGE INCLUDING THE SAME

(71) Applicant: SAMSUNG ELECTRONICS CO, LTD., Suwon-si (KR)

(72) Inventors: JAEYONG PARK, Suwon-si (KR); TAEHYEONG KIM, Suwon-si (KR); DONGJOO CHOI, Suwon-si (KR)

(73) Assignee: SAMSUNG ELECTRONICS CO, LTD., Suwon-si (KR)

(21) Appl. No.: 18/591,546

(22) Filed: Feb. 29, 2024

(30) Foreign Application Priority Data
Sep. 21, 2023 (KR) 10-2023-0126564
Jan. 15, 2024 (KR) 10-2024-0005999

(51) Int. Cl. H01L 23/00; H01L 25/065; H10B 80/00

(52) U.S. Cl. CPC H01L 24/06; H01L 24/16; H01L 25/0657; H10B 80/00; H01L 2224/0603; H01L 2224/16148; H01L 2225/06513; H01L 2225/06541; H01L 2225/06589; H01L 2225/06596; H01L 2924/1431; H01L 2924/3511

(57) ABSTRACT

A semiconductor chip may include a body, and first bump pads disposed on a front surface of the body, including signal bump pads and power bump pads. The signal bump pads may be disposed in a central region of the body in a first direction along a second direction crossing the first direction. The power bump pads may include first power bump pads disposed along the first direction in a central region of the body in the second direction, and the second power bump pads may be disposed along the second direction on both sides of the first power bump pads in the first direction.

### CROSS-REFERENCE TO RELATED APPLICATIONS

This application claims priority to and the benefit of Korean Patent Application No. 10-2023-0126564, filed in the Korean Intellectual Property Office on Sep. 21, 2023, and Korean Patent Application No. 10-2024-0005999, filed in the Korean Intellectual Property Office on Jan. 15, 2024, the entire contents of which are incorporated herein by reference.

### BACKGROUND

### (a) Technical Field

Embodiments of the present disclosure relate to a semiconductor chip and a semiconductor package including the same.

### (b) Description of Related Art

In the semiconductor industry, high bandwidth memory (HBM) may provide high bandwidth and low power consumption. In the high bandwidth memory, memory chips are stacked in a vertical direction and may be electrically connected to each other through through-silicon vias (TSVs) and micro-bumps.

As higher density, higher performance, and power efficiency of high-bandwidth memory are required, the size of bumps for connecting respective memory chips is decreasing while the number of bumps is increasing. Accordingly, a method for efficiently arranging the bumps to prevent defects due to the arrangement of the bumps is required.

### SUMMARY

According to embodiments of the present disclosure, a semiconductor chip and a semiconductor package including the same capable of preventing an electric short between conductive bumps are provided.

According to embodiments of the present disclosure, a semiconductor chip and a semiconductor package including the same capable of preventing a wetting defect of a conductive bump are provided.

According to embodiments of the present disclosure, a semiconductor chip is provided and includes a body, and first bump pads disposed on a front surface of the body, the first bump pads including signal bump pads and power bump pads, wherein the signal bump pads are disposed in a central region of the front surface of the body, in a first direction, along a second direction crossing the first direction. The power bump pads include: first power bump pads disposed along the first direction in a central region of the front surface of the body in the second direction; and second power bump pads disposed along the second direction on both sides of the first power bump pads in the first direction.

According to embodiments of the present disclosure, a semiconductor chip is provided and includes a body; and first bump pads disposed on a front surface of the body, the first bump pads including signal bump pads and power bump pads, wherein each of the signal bump pads and the power bump pads are disposed apart from edges of the front surface of the body by at least 900 μm.

According to embodiments of the present disclosure, a semiconductor package is provided and includes a plurality of first semiconductor chips that are stacked, and a second semiconductor chip. Each of the plurality of first semiconductor chips includes: a first body including a front surface and a rear surface, opposite to the front surface; first bump pads disposed on the front surface of the first body; second bump pads disposed on the rear surface of the first body; first through vias electrically connecting the first bump pads and the second bump pads by penetrating at least a portion of the first body; and conductive bumps disposed on each of the first bump pads. The second semiconductor chip is disposed on the front surface of a lowermost one of the plurality of first semiconductor chips and includes: a second body including a front surface and a rear surface, opposite to the front surface of the second body; third bump pads disposed on the front surface of the second body; fourth bump pads disposed on the rear surface of the second body; and second through vias that electrically connect the third bump pads and the fourth bump pads by penetrating at least a portion of the second body. The conductive bumps of one of the plurality of first semiconductor chips electrically connect the first bump pads of the one of the plurality of first semiconductor chips to a second bump pad of another one of the plurality of first semiconductor chips or the fourth bump pads of the second semiconductor chip. The first bump pads include signal bump pads and power bump pads. The signal bump pads are disposed in a central region of the front surface of the first body, in a first direction, along a second direction crossing the first direction. The power bump pads include: first power bump pads disposed along the first direction in a central region of the first body in the second direction; and second power bump pads disposed along the second direction on both sides of the first power bump pads in the first direction. The signal bump pads and the power bump pads are disposed apart from edges of the front surface of the first body by at least 900 μm.

### BRIEF DESCRIPTION OF THE DRAWINGS

FIG. 1 is a cross-sectional view of a semiconductor package applied with an arrangement of bump pads according to an embodiment of the present disclosure.

FIG. 2 is an enlarged view of bump pads and a surrounding region of a semiconductor chip.

FIG. 3 shows an example arrangement of bump pads of a semiconductor chip.

FIG. 4 is a first drawing for explaining defects that may occur in a semiconductor package.

FIG. 5 is a second drawing for explaining defects that may occur in a semiconductor package.

FIG. 6 shows an example arrangement of bump pads according to an embodiment of the present disclosure.

FIG. 7 shows an example arrangement of bump pads according to an embodiment of the present disclosure.

FIG. 8 shows an example arrangement of test pads, together with the bump pads shown in FIG. 7.

FIG. 9 shows an example arrangement of heat-dissipation bump pads, together with the bump pads shown in FIG. 7.

FIG. 10 shows an example arrangement of dummy bump pads, together with the bump pads shown in FIG. 7.

FIG. 11 is a cross-sectional view of a semiconductor package applied with an arrangement of bump pads according to an embodiment of the present disclosure.

### DETAILED DESCRIPTION

Non-limiting example embodiments of the present disclosure will be described more fully hereinafter with reference to the accompanying drawings. As those skilled in the art would realize, the described example embodiments may be modified in various different ways, all without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings may be arbitrarily given for better understanding and ease of description, the present disclosure is not limited to the illustrated sizes and thicknesses. In the drawings, the thickness of layers, films, panels, regions, etc., may be exaggerated for clarity. For better understanding and ease of description, the thickness of some layers and areas may be exaggerated.

Throughout this specification and the claims that follow, when it is described that an element is “coupled/connected” to another element, the element may be “directly coupled/connected” to the other element or “indirectly coupled/connected” to the other element through a third element. In a similar perspective, this includes not only cases where it is “physically coupled”, but also the cases where it is “electrically coupled.”

In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, sequential numbers such as “first” and “second” are used to distinguish a certain component from another component that is the same or similar to the certain component, and are not necessarily intended to refer to a specific component. Accordingly, a component referred to as a first component in a particular portion of the specification may be referred to as a second component in another portion of the specification.

In addition, throughout the specification, a singular reference to a component includes references to a plurality of these components, unless specifically stated to the contrary. For example, “an insulation layer” may be used to mean not only one insulation layer but also a plurality of insulation layers such as two, three, or more insulation layers.

In addition, throughout the specification, references to one (or first) surface and the other (or second) surface are intended to distinguish different surfaces from each other, and are not necessarily intended to limit it to a specific surface. Therefore, a surface referred to as one (or first) surface in a specific portion of the specification may be referred to as the other (or second) surface in another portion of the specification.

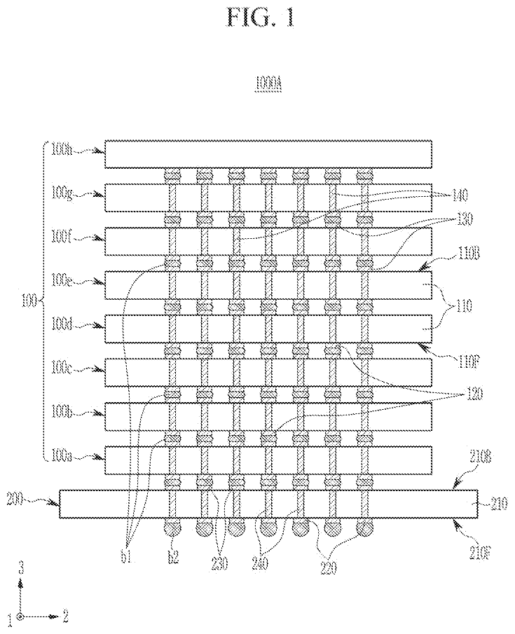

FIG. 1 is a cross-sectional view of an semiconductor package applied with an arrangement of bump pads according to an embodiment of the present disclosure.

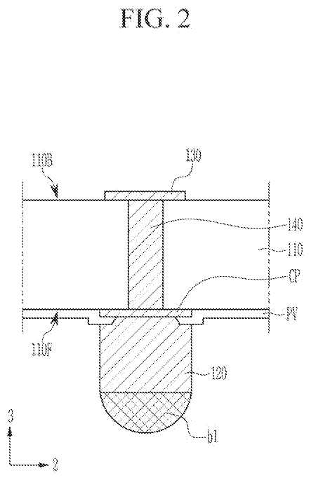

FIG. 2 is an enlarged view of bump pads and a surrounding region of a semiconductor chip.

A semiconductor package 1000A may include a plurality of first semiconductor chips 100, that are stacked, and a second semiconductor chip 200.

For example, the semiconductor package 1000A may include the second semiconductor chip 200 and eight first semiconductor chips (e.g., a lowermost first semiconductor chip 100a, a first semiconductor chip 100b, a first semiconductor chip 100c, 100d, a first semiconductor chip 100e, a first semiconductor chip 100f, a first semiconductor chip 100g, and an uppermost first semiconductor chip 100h) stacked thereon.

Referring to FIG. 1, each of the first semiconductor chips 100 may include a body 110 having a front surface 110F and a rear surface 110B opposite of each other, first bump pads 120 disposed on the front surface 110F of the body 110, second bump pads 130 disposed on the rear surface 110B of the body 110, through vias 140 each penetrating at least a portion of the body 110 to electrically connect the first bump pads 120 and the second bump pads 130, and conductive bumps b1. However, another semiconductor chip may not be disposed on the uppermost first semiconductor chip 100h among the first semiconductor chips 100, and the uppermost first semiconductor chip 100g may not include second bump pads 130 and through vias 140 for electrical connection to another semiconductor chip.

The first bump pads 120, the second bump pads 130, the through vias 140, and the conductive bumps b1 may be provided in a plural quantity, respectively.

The body 110 may include a semiconductor substrate such as silicon, and a plurality of individual devices (e.g., transistors or the like), internal circuits, interlayer insulating layers, or the like formed through front end of line (FEOL) and back end of line (BEOL) processes, or the like.

The first bump pads 120 may be a configuration for electrically connecting at least one of the first semiconductor chips 100 to another component through the conductive bumps b1.

Referring to FIG. 2, the first semiconductor chips 100 may include a chip pad CP located on the front surface 110F of the body 110, and one of the first bump pads 120 may be disposed on the chip pad CP and electrically connected thereto. The chip pad CP may be electrically connected to an internal circuit of the body 110, and may be formed of a conductive material such as aluminum (Al), copper (Cu), or the like.

In addition, on the front surface 110F of the body 110 of the first semiconductor chips 100, a passivation layer PV for protecting the semiconductor chips 100 may be additionally disposed. The passivation layer PV may have an opening exposing the chip pad CP, and may be formed of an insulating property material such as silicon oxide, silicon nitride layer, or the like.

Each of the first bump pads 120 may perform various functions depending on designs. For example, the first bump pads 120 may include signal bump pads for transferring signals to the first semiconductor chips 100, power bump pads for supplying power, heat-dissipation bump pads for dissipation of heat of the first semiconductor chips 100, dummy bump pads, or the like. A specific arrangement of the first bump pads 120 will be described later.

The second bump pads 130 may electrically connect the first semiconductor chips 100 to another configuration. One of the conductive bumps b1 of another one of the first semiconductor chips 100 may be disposed on the second bump pad 130, and through this, two of the first semiconductor chips 100 may be electrically connected. The second bump pads 130 of one of the first semiconductor chips 100 may have an arrangement corresponding to the first bump pads 120 of another one of the first semiconductor chips 100 electrically connected thereto.

A conductive material may be used as the material of each of the first bump pads 120 and the second bump pads 130, and for example, a metal such as copper (Cu), nickel (Ni), or the like, or an alloy of metals may be used.

Each of the first bump pads 120 and the second bump pads 130 may have a quadrangular shape such as a square or a rectangle, and may have a circular shape.

Each of the through vias 140 may penetrate at least a portion of the body 110 to electrically connect one of the first bump pads 120 and one of the second bump pads 130. In addition, each of the through vias 140 may also be electrically connected to the chip pad CP and the internal circuit of the body 110.

A conductive material such as copper may also be used as a material of the through vias 140, and an insulative barrier layer may be additionally disposed on a side surface of the through vias 140.

A plurality of the conductive bumps b1 may be disposed between the plurality of first semiconductor chips 100 and/or between the lowermost first semiconductor chip 100a and the second semiconductor chip 200, and may electrically connect the first bump pad 120 of one of the first semiconductor chips 100 to the second bump pad 130 of another one of the first semiconductor chips 100 or a fourth bump pad 230 of the second semiconductor chip 200.

Referring to FIG. 2, with respect to one or more of the first semiconductor chips 100, each of the conductive bumps b1 may be disposed on one of the first bump pads 120. The conductive bumps b1 may respectively overlap the first bump pads 120 in a plan view, and the arrangement of a plurality of the conductive bumps b1 may depend on the arrangement of the first bump pads 120. According to embodiments of the present disclosure, a metal thin film of gold (Au) or the like may be additionally disposed between the first bump pads 120 and the conductive bumps b1.

The conductive bumps b1 may be formed as, for example, Sn/Ag solder, ball, cap, or the like. In addition, the conductive bumps b1 may each be a micro bump having a diameter of several tens to several hundreds of microns.

According to embodiments of the present disclosure, the semiconductor package 1000A may further include a underfill member covering the conductive bumps b1.

The first semiconductor chips 100 each may be a high bandwidth memory chip for configuring a high bandwidth memory (HBM) package. In the technical field of the present disclosure, the first semiconductor chip 100 may be referred to as a core chip, a slave chip, or the like.

The number of the first semiconductor chips 100 may not be limited to the number shown in the drawings, and may be more or less than the number shown in the drawings.

The second semiconductor chip 200 may be disposed on the front surface 110F of the lowermost first semiconductor chip 100a among the plurality of first semiconductor chips 100.

The second semiconductor chip 200 may include a body 210 having a front surface 210F and a rear surface 210B opposite to each other, third bump pads 220 disposed on the front surface 210F of the body 210, fourth bump pads 230 disposed on the rear surface 210B of the body 210, through vias 240 each penetrating at least a portion of the body 210 to electrically connect the third bump pads 220 and the fourth bump pad 230, and conductive bumps b2.

The description on the body 110, the first bump pads 120, the second bump pads 130, the through vias 140, and the conductive bumps b1 of the first semiconductor chip 100 in the present disclosure may also be applied to the body 210, the third bump pads 220, the fourth bump pad 230, the through vias 240, and the conductive bumps b2 of the second semiconductor chip 200 unless there is a particular contradiction, and a redundant description thereof is not included herein.

The second semiconductor chip 200 may be a logic chip for configuring a high bandwidth memory package. In the technical field of the present disclosure, the second semiconductor chip 200 may be referred to as a buffer chip, a base chip, or the like.

According to embodiments of the present disclosure, the semiconductor package 1000A may further include a molding material for molding the plurality of first semiconductor chips 100, or the plurality of first semiconductor chips 100 and the second semiconductor chip 200.

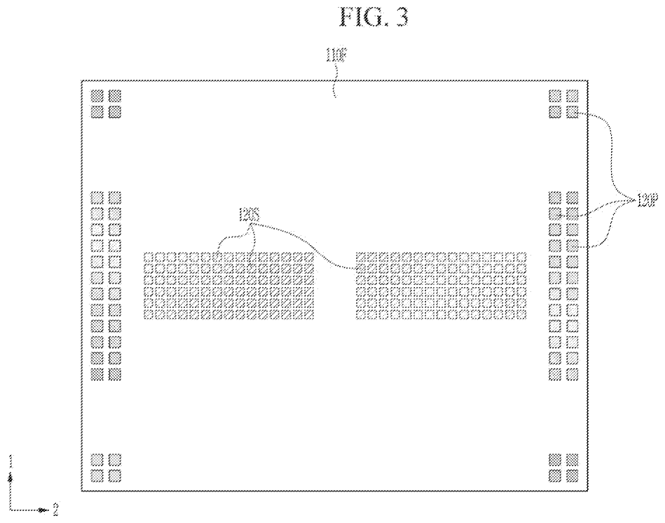

FIG. 3 shows an example arrangement of bump pads of a semiconductor chip.

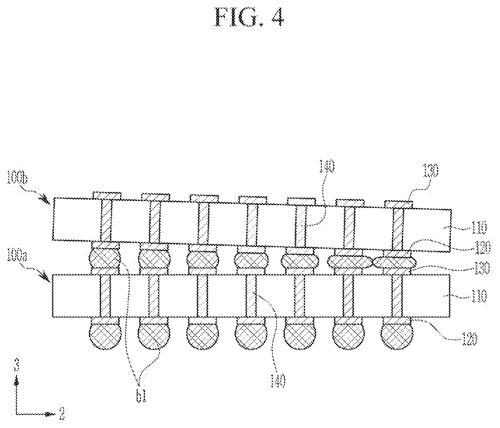

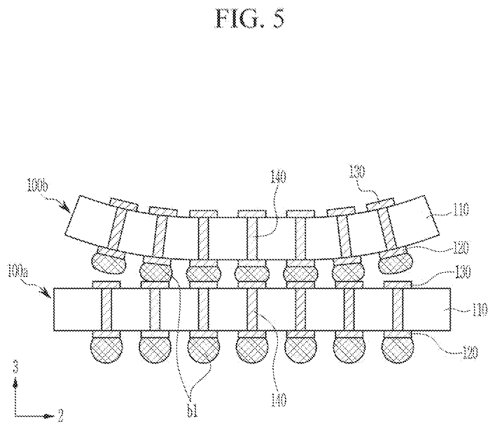

FIG. 4 and FIG. 5 are drawings for explaining defects that may occur in a semiconductor package.

FIG. 4 and FIG. 5 illustrate the defects, for example, with respect to the lowermost first semiconductor chip 100a and the first semiconductor chip 100b.

When manufacturing a semiconductor chip, for signal quality, signal bump pads 120S are preferentially disposed on an inner portion of the front surface 110F of the body 110, and then for convenience of design, power bump pads 120P may be disposed on an outer part of the front surface 110F of the body 110 (at an outer side of signal bump pads 120S). For example, as shown in FIG. 3, the signal bump pads 120S may be disposed in a central region of the body 110 in a first direction 1 along a second direction 2 crossing the first direction 1, and the power bump pads 120P may be disposed on both side edge regions of the body 110 in the second direction 2.

In such a case, when the first semiconductor chip 100b is tilt at the time of disposing the first semiconductor chip 100b on the lowermost first semiconductor chip 100a, an electric short may occur between the conductive bumps b1 disposed on the power bump pads 120P disposed in an edge region of the body 110 (refer to FIG. 4).

In addition, due to the warpage of the first semiconductor chip 100b, a wetting defect in which the conductive bumps b1 disposed on the power bump pads 120P disposed in a corner region of the body 110 are not coupled to the second bump pads 130 of the lowermost first semiconductor chip 100a may occur (refer to FIG. 5).

These defects may become more severe as the size of the conductive bumps decreases and the number of conductive bumps increases as semiconductor chips become more dense, high-performance, and power-efficient. Accordingly, the inventors came up with a novel arrangement of bump pads 120 that may prevent defects that may occur in conductive bumps.

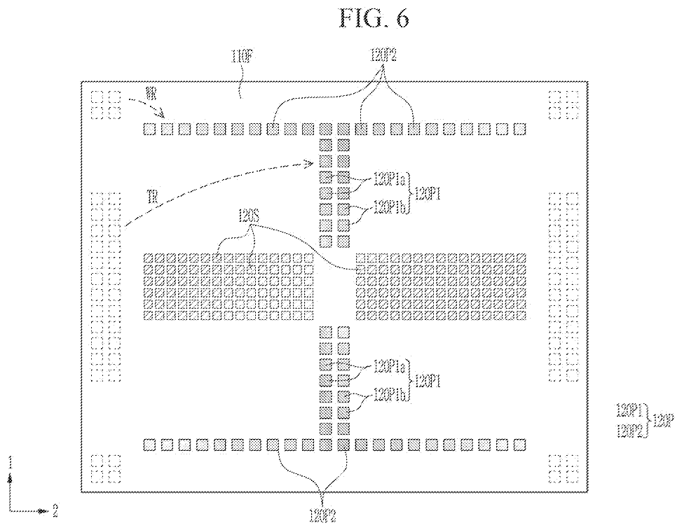

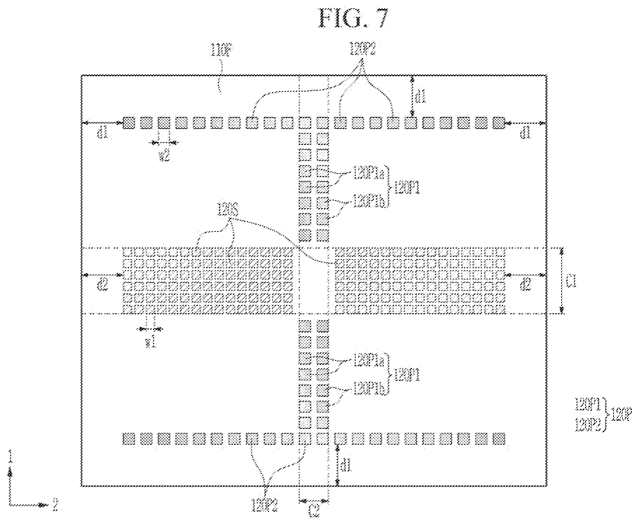

FIG. 6 and FIG. 7 show example arrangements of bump pads according to embodiments of the present disclosure.

As described above, for signal quality, the signal bump pads 120S may be disposed in a central region C1 of the body 110, in the first direction 1, along the second direction 2 crossing the first direction 1.

For implementation of fine pitches, a size of each of the signal bump pads 120S may be smaller than a size of each of the power bump pads 120P. In addition, a distance interval of the signal bump pads 120S may be smaller than a distance interval of the power bump pads 120P. For example, a width w1 of each of the signal bump pads 120S may be about 15 μm, and a width w2 of each of the power bump pads 120P may be about 27 μm. In the present disclosure, the width may mean a width in the first direction 1 or the second direction 2. The width in the first direction 1 and the width in the second direction 2 be may be the same, but may be different from each other.

According to embodiments of the present disclosure, the power bump pads 120P may be disposed to be away from a region TR where the defect may occur due to tilting of the semiconductor chip, and a region WR where the defect may occur due to warpage of the semiconductor chip.

In an embodiment, the power bump pads 120P may be disposed apart from an edge of the front surface 110F of the body 110 by at least 900 μm, and the power bump pads 120P may not be disposed in a region of which a distance to the edge of the front surface 110F of the body 110 is less than 900 μm. In other words, a distance d1 from the power bump pads 120P to the edge of the front surface 110F of the body 110 may be 900 μm or more. Alternatively, the distance d1 from the power bump pads 120P to the edge of the front surface 110F of the body 110 may be 2 mm or more. In the present disclosure, a distance between components may mean a minimum distance between them.

According to embodiments of the present disclosure, the power bump pads 120P are disposed apart from edge of the body 110 by more than a predetermined distance, and thereby the electric short and wetting defect of the conductive bumps b1 may be prevented. The inventors have confirmed through experiments that defects due to tilting and warpage of the semiconductor chip were not reproduced when employing the arrangement of the power bump pads 120P according to embodiments of the present disclosure.

In an embodiment, the power bump pads 120P may include first power bump pads 120P1 disposed in a central region C2 of the body 110, in the second direction 2, along the first direction 1, and second power bump pads 120P2 disposed along the second direction 2 on both sides of the first power bump pads 120P1 in the first direction 1. However, according to embodiments, the power bump pads 120P may only include the first power bump pads 120P1 or the second power bump pads 120P2.

When the first direction 1 is referred to as a column direction and the second direction 2 is referred to as a row direction, the first power bump pads 120P1 may form a plurality of columns. For example, as shown in FIGS. 6-7, the first power bump pads 120P1 may form two columns, and thereby may include 1-1-st power bump pads 120P1a and 1-2-nd power bump pads 120P1b spaced apart from each other in the second direction 2. However, embodiments of the present disclosure are not limited thereto, and the first power bump pads 120P1 may form more or less columns than shown in the drawings.

In order to minimize the influence of the signal bump pads 120S on signal transmission, the first power bump pads 120P1 may not be disposed in the central region C1 of the body 110 in the first direction 1 where the signal bump pads 120S are disposed.

The second power bump pads 120P2 may be spaced apart from the signal bump pads 120S in the first direction 1 by the first power bump pads 120P1. Although it is illustrated that the second power bump pads 120P2 are disposed on both sides of the first power bump pads 120P1 to form one row for each side, it is not limited thereto, and a plurality of rows may be formed.

According to an embodiment, the first power bump pads 120P1 and the second power bump pads 120P2 are disposed on the inner portion of the front surface 110F of the body 110 thereby preventing defect of the conductive bumps b1, and in addition, the first power bump pads 120P1 may be disposed in a direction crossing the signal bump pads 120S, and the second power bump pads 120P2 may be disposed apart from the signal bump pads 120S, thereby minimizing the influence of the power bump pads 120P on signal transmission.

In addition, the power bump pads 120P may be symmetrically arranged on the front surface 110F of the body 110 with respect to each of the first direction 1 and the second direction 2, and through this, power may be supplied to the entire region of the first semiconductor chip 100. For example, the first power bump pads 120P1 are disposed in the central region C2 in the second direction 2 of the front surface 110F of the body 110, and accordingly, power may be equally supplied to both sides of the first semiconductor chip 100 in the second direction 2. In addition, the second power bump pads 120P2 are disposed on the both sides of the first power bump pads 120P1, and accordingly, power may be equally supplied to both sides of the first semiconductor chip 100 in the first direction 1.

According to embodiments of the present disclosure, in order to prevent the electric short and wetting defect, the signal bump pads 120S may also be disposed apart from the edge of the front surface 110F of the body 110 by at least 900 μm, and the signal bump pads 120S may not be disposed in a region of which a distance to the edge of the front surface 110F of the body 110 is less than 900 μm. In other words, a distance d2 from the signal bump pads 120S to the edge of the front surface 110F of the body 110 may also be 900 μm or more. Alternatively, the distance d1 from the signal bump pads 120S to the edge of the front surface 110F of the body 110 may be 2 mm or more.

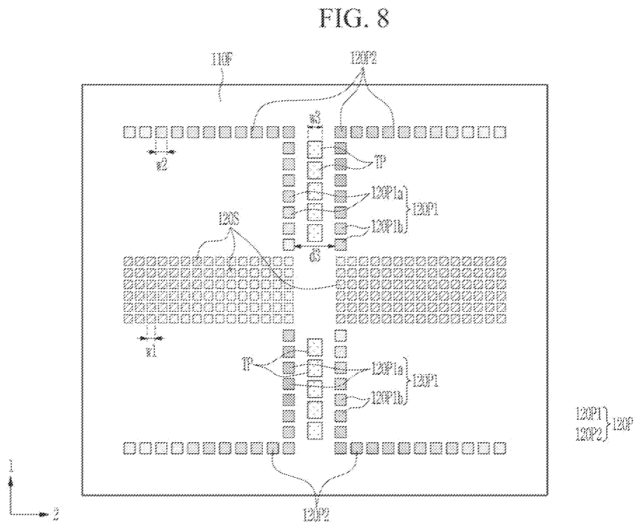

FIG. 8 shows an example arrangement of test pads, together with the bump pads shown in FIG. 7.

The first semiconductor chip 100 may further include test pads TP for electrical inspection of the semiconductor chip. Since test pads TP is not for electrical connection to another semiconductor chip, the conductive bumps b1 may not be disposed on test pads TP.

Referring to the drawings, test pads TP may be disposed between the 1-1-st power bump pads 120P1a and the 1-2-nd power bump pads 120P1b. The drawings illustrate that test pads TP form one row between the 1-1-st power bump pads 120P1a and 1the-2-nd power bump pads 120P1b, but they may be disposed to form a plurality of columns.

A width w3 of each of the test pads TP may be about 60 μm to 70 μm. For example, a width of each of the test pads TP in the first direction 1 may be 70 μm, and a width in the second direction 2 may be 60 μm.

In order to arrange the test pads TP, a distance interval d3 between the 1-1-st power bump pads 120P1a and the 1-2-nd power bump pads 120P1b may be at least 90 μm.

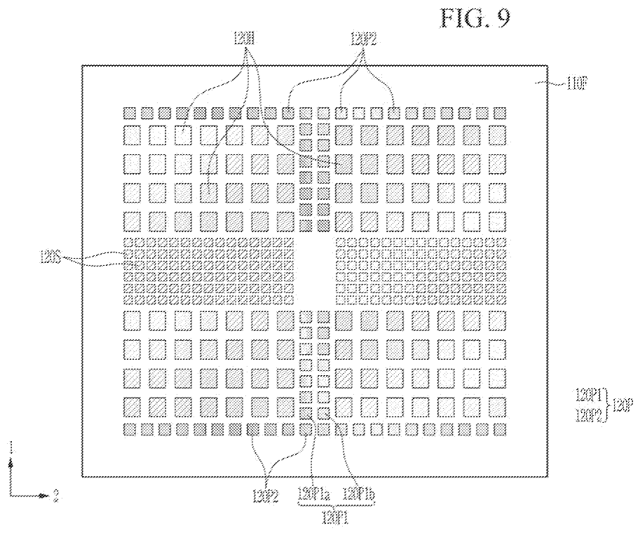

FIG. 9 shows an example arrangement of heat-dissipation bump pads, together with the bump pads shown in FIG. 7.

The first bump pads 120 disposed on the front surface 110F of the body 110 may further include heat-dissipation bump pads 120H for dissipating the heat generated in or transferred to the semiconductor chip 100. The conductive bumps b1 may be disposed on the heat-dissipation bump pads 120H, so as to form a heat transfer path. The heat-dissipation bump pads 120H may be disposed, for example, between the signal bump pads 120S and the second power bump pads 120P2, but the arrangement of the heat-dissipation bump pads 120H is not limited thereto.

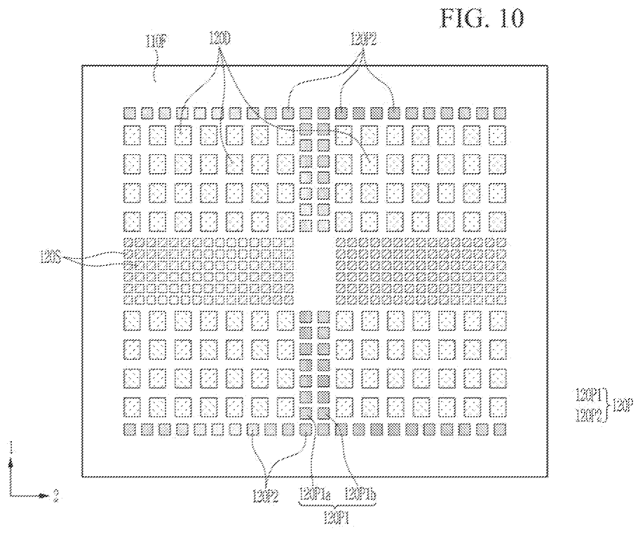

FIG. 10 shows an example arrangement of dummy bump pads, together with the bump pads shown in FIG. 7.

The first bump pads 120 disposed on the front surface 110F of the body 110 may further include dummy bump pads 120D. The dummy bump pads 120D may reduce the filing amount of the underfill to cover the conductive bumps b1, and it may not matter whether the electric short occurs between them or they are not electrically connected to another semiconductor chip. The dummy bump pads 120D are not limited to a particular arrangement, and may be disposed in a remaining space after disposing other bump pads such as the signal bump pads 120S, the power bump pads 120P, and heat-dissipation bump pads 120H.

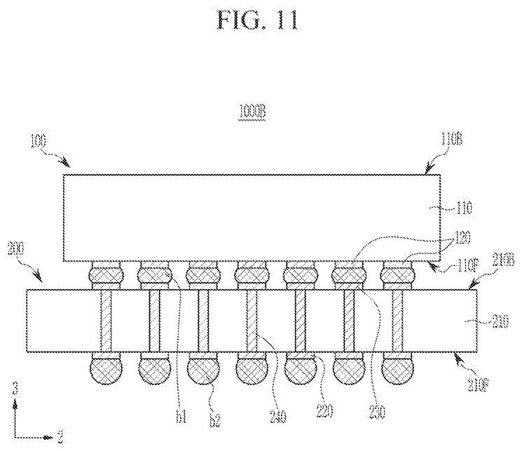

FIG. 11 is a cross-sectional view of another example semiconductor package applied with an arrangement of bump pads according to an embodiment of the present disclosure.

A semiconductor package 1000B may include a single first semiconductor chip 100 and a single second semiconductor chip 200.

The first bump pads 120 according to embodiments of the present disclosure may also be applied to other packages as well as to the high bandwidth memory package. For example, it may be applied to a three-dimensional integrated circuit (3D-IC) structure in which the first semiconductor chip 100 and the second semiconductor chip 200 are stacked in a third direction 3.

The first semiconductor chip 100 may include the body 110 having the front surface 110F and the rear surface 110B opposite to each other, the first bump pads 120 disposed on the front surface 110F of the body 110, and the conductive bumps b1, but may not include the second bump pads 130 and the through vias 140.

Since the contents described above may be equally applied to other components, a redundant description is not included herein.

While non-limiting example embodiments of the present disclosure have been described, it is to be understood that the disclosure is not limited to the example embodiments, and, on the contrary, is intended to cover various modifications and equivalent arrangements included within the spirit and scope of the present disclosure.

Embodiments of the present disclosure may not be independent from each other and may be implemented in a combination with each other unless there is a particular conflict. Combined forms of the present embodiments are also within the scope of the present disclosure.

What is claimed is:

1. A semiconductor chip, comprising:
a body; and
first bump pads disposed on a front surface of the body, the first bump pads comprising signal bump pads and power bump pads,
wherein the signal bump pads are disposed in a central region of the front surface of the body, in a first direction, along a second direction crossing the first direction, and
wherein the power bump pads comprise:
first power bump pads disposed along the first direction in a central region of the front surface of the body in the second direction; and
second power bump pads disposed along the second direction on both sides of the first power bump pads in the first direction.

2. The semiconductor chip of claim 1, wherein each of the signal bump pads and the power bump pads are apart from edges of the front surface of the body by at least 900 μm.

3. The semiconductor chip of claim 1, wherein the second power bump pads are not disposed in the central region in the first direction of the body where the signal bump pads are disposed.

4. The semiconductor chip of claim 1, wherein
the first power bump pads comprise 1-1-st power bump pads and 1-2-nd power bump pads, the 1-1-st power bump pads spaced apart from the 1-2-nd power bump pads in the second direction, and
the semiconductor chip further comprises at least one test pad disposed between the 1-1-st power bump pads and the 1-2-nd power bump pads.

5. The semiconductor chip of claim 4, wherein a distance interval between the 1-1-st power bump pads and the 1-2-nd power bump pads is at least 90 μm.

6. The semiconductor chip of claim 1, wherein the first bump pads further comprise heat-dissipation bump pads.

7. The semiconductor chip of claim 1, wherein the first bump pads further comprise dummy bump pads.

8. The semiconductor chip of claim 1, wherein the power bump pads are symmetrically arranged on the front surface of the body with respect to each of the first direction and the second direction.

9. The semiconductor chip of claim 1, wherein a size of the signal bump pads is smaller than a size of the power bump pads.

10. The semiconductor chip of claim 1, wherein a distance interval of the signal bump pads is smaller than a distance interval of the power bump pads.

11. The semiconductor chip of claim 1, wherein the semiconductor chip further comprises second bump pads disposed on a rear surface of the body, opposite to the front surface of the body, and through vias that electrically connect the first bump pads and the second bump pads by penetrating at least a portion of the body.

12. The semiconductor chip of claim 1, wherein the semiconductor chip further comprises conductive bumps disposed on the signal bump pads and the power bump pads.

13. A semiconductor chip, comprising:
a body; and
first bump pads disposed on a front surface of the body, the first bump pads comprising signal bump pads and power bump pads,
wherein each of the signal bump pads and the power bump pads are disposed apart from edges of the front surface of the body by at least 900 μm.

14. The semiconductor chip of claim 13, wherein the semiconductor chip further comprises:
second bump pads disposed on a rear surface of the body, opposite to the front surface of the body; and
through vias electrically connecting the first bump pads and the second bump pads by penetrating at least a portion of the body.

15. A semiconductor package, comprising:
a plurality of first semiconductor chips that are stacked; and
a second semiconductor chip,
wherein each of the plurality of first semiconductor chips comprises:
a first body comprising a front surface and a rear surface, opposite to the front surface;
first bump pads disposed on the front surface of the first body;
second bump pads disposed on the rear surface of the first body;
first through vias electrically connecting the first bump pads and the second bump pads by penetrating at least a portion of the first body; and
conductive bumps disposed on each of the first bump pads;
wherein the second semiconductor chip is disposed on the front surface of a lowermost one of the plurality of first semiconductor chips and comprises:
a second body comprising a front surface and a rear surface, opposite to the front surface of the second body;
third bump pads disposed on the front surface of the second body;
fourth bump pads disposed on the rear surface of the second body; and
second through vias that electrically connect the third bump pads and the fourth bump pads by penetrating at least a portion of the second body,
wherein the conductive bumps of one of the plurality of first semiconductor chips electrically connect the first bump pads of the one of the plurality of first semiconductor chips to a second bump pad of another one of the plurality of first semiconductor chips or the fourth bump pads of the second semiconductor chip,
wherein the first bump pads comprise signal bump pads and power bump pads,
wherein the signal bump pads are disposed in a central region of the front surface of the first body, in a first direction, along a second direction crossing the first direction,
wherein the power bump pads comprise:
first power bump pads disposed along the first direction in a central region of the first body in the second direction; and
second power bump pads disposed along the second direction on both sides of the first power bump pads in the first direction, and
wherein the signal bump pads and the power bump pads are disposed apart from edges of the front surface of the first body by at least 900 μm.

16. The semiconductor package of claim 15, wherein the second power bump pads are not disposed in the central region of the first body in the first direction where the signal bump pads are disposed.

17. The semiconductor package of claim 15, wherein the conductive bumps overlap the first bump pads in a plan view.

18. The semiconductor package of claim 15, wherein the first bump pads further comprise heat-dissipation bump pads.

19. The semiconductor package of claim 15, wherein the first bump pads further comprise dummy bump pads.

20. The semiconductor package of claim 15, wherein:
the plurality of first semiconductor chips comprise a high bandwidth memory (HBM) chip; and
the second semiconductor chip is a logic chip.
